(19) United States
(12) Patent Application Publication
(10) Pub. No.: US 2006/0181861 A1
(43) Pub. Date: Aug. 17, 2006

(54) Etched leadframe for reducing metal gaps

(76) Inventor: Harold Young Walker JR., Plano, TX (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/354,199

(22) Filed: Feb. 14, 2006

Related U.S. Application Data
(60) Provisional application No. 60/653,788, filed on Feb. 17, 2005.

(51) Int. Cl. H05K 5/02; H01R 43/00

(52) U.S. Cl. 361/813; 361/807; 29/827; 29/832

(57) ABSTRACT

A leadframe is disclosed having an unreduced leadframe thickness. The leadframe includes a portion of reduced thickness. The portion of reduced thickness can be created by a subtractive process, such as an etching process. The leadframe further includes a gap located within the portion of reduced thickness. The gap is located between metal portions of the leadframe and extends through at least a portion of the reduced thickness. The width of the gap can be less than the unreduced leadframe thickness as a result of the portion of reduced thickness.

### CROSS-REFERENCE TO RELATED APPLICATIONS

This application claims the benefit of U.S. Provisional Patent Application No. 60/653,788, filed Feb. 17, 2005, which is incorporated herein by reference in its entirety.

### BACKGROUND OF THE INVENTION

1. The Field of the Invention

The present invention is generally related to fabrication of leadframes for use with semiconductor chips. More specifically, the present invention is related to reducing the required gap width between metal portions of a leadframe while retaining leadframe rigidity and functionality.

2. Related Technology

Semiconductor chips typically include a semiconductor die electrically coupled to a leadframe and encased, or enclosed, in a packaging material such as a plastic casing. The plastic casing provides protection while allowing for portions of the leadframe to extend beyond the casing for electrical coupling between the semiconductor die and an external device such as a printed circuit board (PCB).

Leadframes are typically formed from a sheet of metal by a subtractive manufacturing process such as metal stamping or an etching process. The manufacturing process removes metal in certain areas, and leaves metal in the shape of the desired leadframe structure. This structure includes die attach areas where the semiconductor die is attached, plus areas around the die attach areas where wire bonds can be attached. The wire bond areas generally extend outside the “main body” of the product as leads, which can then be used to electrically connect to the product and secure the product to an assembly.

One design constraint in the fabrication of leadframes is that the gap between any two pieces of metal cannot be narrower than the thickness of the metal itself. Thus, for stamped leadframes, a significant constraint is the thickness of the material (actually the thinness). For materials in the 0.005-0.020 inch range, the steel blades that cut through the metal during the process of manufacturing the leadframe become very thin and thus very fragile creating a manufacturing constraint. However, if the metal thickness is 0.040 or more, the metal blades become much stronger, and the width of the gaps can be less than material thickness.

For etched leadframes, the linewidth is controlled by the opening in the mask that is applied to the metal strip. This “window” limits where the acid will attack the metal. However, as the acid starts etching down into the metal, the acid also starts etching laterally into the body of the metal. To control the etching, the window must be made narrower than the width to be etched. Again, where very thin metal strips are being used, it is difficult to make the starting window small enough and still be able to apply acid at the proper location to etch the metal. There may also be additional process limitations to manufacturing thin gaps in leadframes.

In some configurations and applications, very narrow gaps between portions of the metal of the leadframe are desirable, but the leadframe must also be thick enough to provide the needed rigidity for the final product creating a functional constraint. In these instances, the gap width desired is less than the thickness of the metal strip and the leadframe may thus be less rigid than what is needed or desirable. Narrow gaps between portions of metal of a leadframe may also be desirable for additional reasons and applications.

Thus, what would be advantageous are methods and apparatus for reducing gaps in a leadframe while retaining rigidity and functionality in the leadframe.

### SUMMARY OF SEVERAL EXAMPLE EMBODIMENTS

In one embodiment of the present invention a leadframe is disclosed. The leadframe includes a portion of the leadframe having an unreduced leadframe thickness. The leadframe further includes a portion of the leadframe having a reduced thickness that is thinner than the unreduced leadframe thickness. The leadframe further includes a gap located within the portion of reduced thickness, the gap being located between metal portions of the leadframe and extending through at least a portion of the reduced thickness, the width of the gap being less than the unreduced leadframe thickness.

According to another embodiment, an electronic component is disclosed. The electronic component includes a circuit coupled to a leadframe. The leadframe is configured to support the circuit and further configured to electrically couple the circuit to a printed circuit board. The leadframe includes an unreduced leadframe thickness. The leadframe further includes a portion of reduced thickness that is less than the unreduced leadframe thickness. The leadframe further includes a gap, the gap having a width that is less than the unreduced leadframe thickness.

According to another embodiment, a method for fabricating a leadframe is disclosed. The method includes providing a metal leadframe having an unreduced leadframe thickness. The method further includes producing a portion of reduced thickness in the leadframe. The method further includes producing a gap in the portion of reduced thickness, the gap having a width less than the unreduced leadframe thickness.

These and other aspects of the present invention will become more fully apparent from the following description and appended claims.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates a portion of a leadframe including etched portions of reduced thickness according to an example embodiment of the present invention;

FIG. 2 illustrates a cross sectional view of a portion of a leadframe centered about an etched portion in the leadframe, the etched portion having a reduced thickness;

FIG. 3 illustrates a top view of a portion of a leadframe centered about a gap in the leadframe; and

FIG. 4 illustrates a method for manufacturing a leadframe.

### DETAILED DESCRIPTION OF SEVERAL EXAMPLE EMBODIMENTS

The present invention relates to fabrication of leadframes, and to reducing gap width between metal portions of the leadframe while retaining leadframe functionality and rigidity. Certain principles of the present invention are described with reference to the attached drawings to illustrate the structure and operation of example embodiments of the present invention.

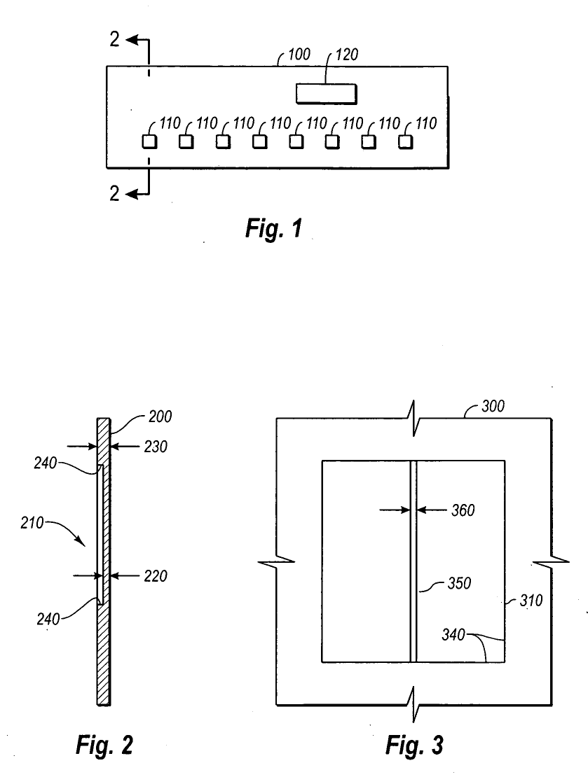

Referring to FIG. 1, a portion of a leadframe 100 is shown according to an example embodiment of the present invention. The portion of the leadframe 100 can be made from a piece of metal that is at least partially stamped or etched to produce the desired shapes and contours of the leadframe. According to the example embodiment shown, the leadframe 100 further includes portions of reduced thickness 110, where the thickness of the leadframe 100 has been reduced relative to the unreduced leadframe thickness of the leadframe 100. The portions of reduced thickness 110 create a reduced thickness of the leadframe 100 in locations where gaps may be produced in the metal of the leadframe 100. As a result of the relative thinness of the portions of reduced thickness 110, gaps formed in the portions of reduced thickness 110 can be narrower than those that would otherwise be possible.

As described above, gaps formed in the leadframe 100 have, in some embodiments, a width about at least as wide as the unreduced thickness of the leadframe 100. By reducing the thickness of the leadframe 100 in the locations of the portions of reduced thickness 110, the width of the gaps can be correspondingly reduced in those locations while other locations can retain their unreduced thickness and rigidity for support and functionality of the leadframe 100 and components placed thereon.

The portions of reduced thickness 110 can be manufactured using any appropriate manufacturing process. For example, the portions of reduced thickness 110 can be produced by an etching process. An etching mask can be laid down to control the location of the etched portions of reduced thickness 110 and the portions of reduced thickness 110 can be produced using any appropriate type of etching process. Referring still to FIG. 1, the portions of reduced thickness 110 are illustrated as square shaped portions of reduced thickness 110 in a substantially symmetrical row. However, the portions of reduced thickness 110 can be any shape and can be placed at any location on the leadframe 100. For example, the portions of reduced thickness 110 can be circular, rectangular, or complex shaped cavities.

The leadframe 100 can include a die attach area(s) where a die is attached, plus areas around the die attach area(s) where wire bonds can be attached. The wire bond areas can extend outside of the “main body” of the device as leads, which can then be used to electrically connect to a device 120, such as an electrical circuit, and secure the device 120, including the leadframe, to an assembly. The leadframe 100 can be produced from a sheet of metal having an unreduced leadframe thickness. The unreduced leadframe thickness can be selected to provide sufficient rigidity and functionality for the device 120, such as a circuit, attached to the leadframe.

Referring to FIG. 2, a cross sectional view of a portion of a leadframe 200 is depicted, where the leadframe 200 includes a portion of reduced thickness 210 etched in the leadframe 200. As shown, the portion of reduced thickness 210 is etched into the metal leadframe 200, reducing the unreduced leadframe thickness 230 to a reduced thickness 220. According to the example embodiment shown in FIG. 2, the reduced thickness 220 can, in one embodiment, be at least approximately half the thickness of the metal unreduced leadframe thickness 230, or more. The etched portion of reduced thickness 210 can be any depth less than the unreduced leadframe thickness 230 and can vary in depth across the width of the portion of reduced thickness 210. Therefore, there may be multiple portions of reduced thickness 210 in a single location. In fact, multiple manufacturing processes, for example multiple etching processes or other subtractive processes, can be implemented to create multiple depths in a portion of reduced thickness 210. The sidewalls 240 of the portion of reduced thickness 210 can also be any configuration. For example, the sidewalls 240 can be sloped, not entirely straight, or non-uniform or can have more complicated configurations.

FIG. 3 illustrates a top view of a portion of a leadframe 300 centered about a portion of reduced thickness 310 having sidewalls 340 etched partially into the leadframe 300. A gap 350 has been produced in the portion of reduced thickness 310. The gap 350 has a width 360 and a depth. In this example, the depth of the gap 350 is equal to the reduced thickness of the portion of reduced thickness 310, for example see reduced thickness 220 in FIG. 2, and the width 360 of the gap 350 can be about equal to the reduced thickness of the portion of reduced thickness 310, for example reduced thickness 220 in FIG. 2, or more. Thus, as a result of producing the portion of reduced thickness 310 of reduced thickness in the leadframe 300, the width 360 of the gap 350 can be less than the unreduced leadframe 300 thickness, for example unreduced leadframe thickness 230 in FIG. 2. The width 360 of the gap 350 can be any width greater than the reduced thickness of the portion of reduced thickness 310 of the leadframe 300. However, as a result of the portion of reduced thickness 310, the gap 360 can have a smaller width than might otherwise be allowed by the thickness of the leadframe 300, for example see unreduced leadframe thickness 230 in FIG. 2. For example, a gap of width 360 in a portion of unreduced thickness would likely violate an operational or manufacturing constraint. This smaller gap width 360 can be used while retaining the rigidity and functionality of the thicker portion, for example see unreduced leadframe thickness 230 in FIG. 2, of the leadframe.

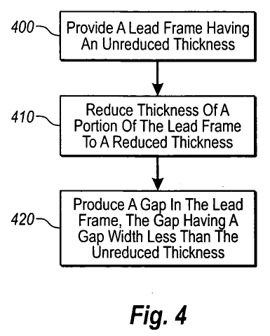

Several different manufacturing methods can be used to produce a leadframe with a portion of reduced thickness and a gap at the location of the portion of reduced thickness with a width at least as wide as the reduced thickness, but less than a thickness of the non-reduced leadframe. For example, referring to FIG. 4, a method for manufacturing a leadframe is illustrated. At 400, a leadframe is provided. The leadframe can be provided by manufacturing the leadframe using a subtractive process to remove portions of a sheet of metallic material. For example, the leadframe can be produced from a sheet of metallic material having an unreduced thickness using a stamping or etching process. The manufacturing process removes metal in certain areas, and leaves metal in the shape of the desired leadframe structure.

The leadframe structure can include die attach area(s) where a die is attached, plus areas around the die attach area(s) where wire bonds can be attached. The wire bond areas can extend outside of the “main body” of the device as leads, which can then be used to electrically connect to a device, such as an electrical circuit, and secure the device, including the leadframe, to an assembly. The unreduced leadframe thickness can be selected to provide sufficient rigidity and functionality for a circuit attached to the leadframe.

At 410, the unreduced leadframe thickness is reduced at a location, or several locations, creating a portion, or portions, of reduced thickness. The portion(s) of reduced thickness can be created using a subtractive manufacturing process, such as an etching process. The portion of reduced thickness can have a substantially square, rectangular, circular, elliptical, or non-uniform shape, for example. A non-uniform shape is a shape that is not symmetric about an axis or point. The portion of reduced thickness can also have a non-uniform thickness across the portion of reduced thickness. The reduced thickness of the portion of reduced thickness can have a thickness that is selected based on a desirable width of a gap, or several gaps, in the portion of reduced thickness. Generally, any configuration with a thickness less then the unreduced portion of the leadframe may be employed.

At 420, a gap, or several gaps, are produced in the leadframe at the location of the portion of reduced thickness, the gap(s) having a width less than the unreduced thickness. The gap extends entirely through the leadframe creating a hole, or slot, in the leadframe. The gap is created using a subtractive process and the width of the gap in one example is less then the unreduced leadframe thickness, but greater than the reduced thickness of at least a portion of the portion of reduced thickness. Because the gap is created at the portion of reduced thickness, the gap may be of a width less than the unreduced leadframe thickness while allowing the leadframe to have the additional rigidity and functionality at the locations of the leadframe having the unreduced leadframe thickness. Thus, the gap can have a width that is less than a functional gap width that would otherwise be non-functional, or violate an operating constraint of the leadframe design, if the gap were in a portion of the leadframe having the unreduced leadframe thickness, for example unreduced leadframe thickness 230 in FIG. 2. Examples of non-functional gaps are discussed in the background section of this application. Thus, the leadframe produced using the method of FIG. 4 can allow for the thin gap width benefits of a thinner leadframe while retaining the functional benefits of a thicker leadframe design. The teachings of this application set forth herein can be applied in many devices and circuit designs and applications where gap width is limited by thickness of electrical components, such as leadframes.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A leadframe comprising:
a portion of the leadframe having an unreduced leadframe thickness;
a portion of the leadframe having a reduced thickness that is thinner than the unreduced leadframe thickness; and
a gap located within the portion of reduced thickness, the gap being located between metal portions of the leadframe and extending through at least a portion of the reduced thickness, the width of the gap being less than the unreduced leadframe thickness.

2. The leadframe of claim 1, wherein the gap width is less than the unreduced leadframe thickness but greater than the reduced thickness.

3. The leadframe of claim 1, wherein the portion of reduced thickness is produced in the leadframe by an etching process.

4. The leadframe of claim 1, wherein the portion of reduced thickness is about half the thickness of the unreduced leadframe thickness.

5. The leadframe of claim 1, wherein the portion of reduced thickness has a substantially square, rectangular, circular, elliptical, or non-uniform shape.

6. The leadframe of claim 1, wherein the portion of reduced thickness has a non-uniform thickness across the portion of reduced thickness.

7. The leadframe of claim 1, wherein a gap having the gap width in the portion of unreduced leadframe thickness violates an operating or manufacturing constraint of the leadframe.

8. The leadframe of claim 7, wherein the operating constraint is a mechanical support for a component supported by the leadframe.

9. An electronic component comprising:
the leadframe of claim 1; and
a circuit supported by the leadframe.

10. An electronic component comprising:
a circuit coupled to a leadframe; and
the leadframe configured to support the circuit and further configured to electrically couple the circuit to a printed circuit board, the leadframe having an unreduced leadframe thickness, the leadframe including a portion of reduced thickness having a thickness less than the unreduced leadframe thickness, the leadframe further including a gap in the portion of reduced thickness, the gap having a width that is less than the unreduced leadframe thickness.

11. An electronic component according to claim 10, further comprising:
a plurality of portions of reduced thickness, each of the plurality of portions of reduced thickness including at least one gap, wherein the gaps each have a width less than the unreduced leadframe thickness.

12. A method for fabricating a leadframe, the method comprising:
providing a metal leadframe having an unreduced leadframe thickness;
producing a portion of reduced thickness in the leadframe; and
producing a gap in the portion of reduced thickness, the gap having a width less than the unreduced leadframe thickness.

13. The method of claim 12, wherein the portions of reduced thickness are produced by an etching process.

14. The method of claim 12, wherein the gaps have a width greater than the reduced thickness but less than the unreduced leadframe thickness.

15. The method of claim 12, wherein the portion of reduced thickness has a substantially square, rectangular, circular, elliptical, or non-uniform shape.

16. The method of claim 12, wherein the portion of reduced thickness has a non-uniform thickness across the portion of reduced thickness.

17. The method of claim 12, wherein the gap width is less than a functional gap width at the unreduced leadframe thickness.

18. The method of claim 12, wherein the width of the gap violates an operating constraint of the leadframe if not for the portion of reduced thickness.

19. A method for fabricating an electrical component, the method comprising:
manufacturing a leadframe according to claim 12; and
attaching a circuit to the leadframe.

20. A method according to claim 19, wherein the leadframe is produced using a subtractive manufacturing process and the circuit is attached to the leadframe using die attach.
